(19) United States
(12) Patent Application Publication
(10) Pub. No.: US 2007/0206411 A1
(43) Pub. Date: Sep. 6, 2007

(54) Magnetic Random Access Memory Devices Including Contact Plugs Between Magnetic Tunnel Junction Structures and Substrates and Related Methods

(76) Inventors: Jang Eun Lee, Gyeonggi-do (KR); Se-Chung Oh, Gyeonggi-do (KR); Jun-Soo Bae, Gyeonggi-do (KR); Hyun-Jo Kim, Gyeonggi-do (KR); Young-Ki Ha, Gyeonggi-do (KR); Kyung-Tae Nam, Gyeonggi-do (KR)

Correspondence Address: MYERS BIGEL SIBLEY & SAJOVEC, PO BOX 37428, RALEIGH, NC, 27627, US

(21) Appl. No.: 11/746,810

(22) Filed: May 10, 2007

Related U.S. Application Data
(63) Continuation-in-part of application No. 11/141,057, filed on Jun. 1, 2005.
Application No. 11/141,057 is a division of application No. 10/376,633, filed on Mar. 3, 2003, now Pat. No. 6,952,364.
(63) Continuation-in-part of application No. 11/145,478, filed on Jun. 3, 2005.

(30) Foreign Application Priority Data
Aug. 9, 2004 (KR) 2004-62635

(51) Int. Cl. G11C 11/14

(52) U.S. Cl. 365/171

(57) ABSTRACT

A magnetic random access memory device may include a semiconductor substrate, a magnetic tunnel junction (MTJ) structure, a contact plug, and a digit line. More particularly, the MTJ structure may be on the semiconductor substrate, and the digit line may be adjacent the magnetic tunnel junction structure. In addition, the contact plug may provide electrical connection between the magnetic tunnel junction structure and the semiconductor substrate, and the contact plug may be between the magnetic tunnel junction structure and the semiconductor substrate. Related methods are also discussed.

### RELATED APPLICATION

This application claims the benefit of priority as a continuation-in-part of U.S. application Ser. No. 11/141,057 filed Jun. 1, 2005, currently pending, which claims the benefit of priority as a divisional of U.S. application Ser. No. 10/376,633 filed Mar. 3, 2003, now issued as U.S. Pat. No. 6,952,364. This application also claims the benefit of priority as a continuation-in-part of U.S. application Ser. No. 11/145,478 filed Jun. 3, 2005, current pending, which claims the benefit of priority from Korean Patent Application No. 2004-62635, filed Aug. 9, 2004. The disclosures of each of the above referenced U.S. and Korean applications are hereby incorporated herein by reference in their entirety as if set forth fully herein.

### FIELD OF THE INVENTION

The present invention relates to memory devices, and more particularly, to magnetic random access memory devices and related methods.

### BACKGROUND

Magnetic random access memory (MRAM) devices may be used to provide nonvolatile memory devices operable at relatively low voltages and at relatively high speeds. In a unit cell of an MRAM device, data is stored in a magnetic tunnel junction (MTJ) structure of a magnetic resistor. The MTJ structure may include first and second ferromagnetic layers and a tunneling insulating layer interposed therebetween. A magnetic polarization of the first ferromagnetic layer (also referred to as a free layer) may be changed using a magnetic field running across the MTJ structure. The magnetic field may be induced by a current flowing around the MTJ structure, and the magnetic polarization of the free layer may be parallel or anti-parallel with respect to the magnetic polarization of the second ferromagnetic layer also referred to as a pinned layer). The current used to generate the magnetic field flows through conductive layers (such as digit and bit lines), disposed adjacent to the MTJ.

In spintronics based on quantum mechanics, a tunneling current flowing through the MTJ structure may have a maximum value when the magnetic spins of the free layer and the pinned layer are aligned in parallel with respect to each other. When the magnetic spins of the free layer and the pinned layer are aligned in anti-parallel with respect to each other, a tunneling current flowing through the MTJ structure may have a minimum value. The cell data of a magnetic RAM device may thus be determined in accordance with a direction of the magnetic spins of the free layer. FIG. 1 is a cross-sectional view illustrating a memory cell of a conventional magnetic RAM device.

Referring to FIG. 1, a lower electrode 3, an MTJ structure t, and an upper electrode 7 are sequentially disposed on a semiconductor substrate T. A digit line 9 is disposed between the lower electrode 3 and the substrate 1. The digit line 9 is disposed to overlap the MTJ structure 5 to apply a uniform magnetic field to the MTJ structure 5. The upper electrode 7 is electrically connected to the bit line 11, which is disposed to run across the digit line 9. The direction of the magnetic spins of the free layer in the MTJ structure 5 may be determined by a current flowing through the digit line 9 and the bit line 11, which are perpendicular with respect to each other. The lower electrode 3 may be electrically connected to an access transistor (not shown) formed in the semiconductor substrate 1. The lower electrode 3, however, may have an extended portion E which does not overlap the digit line 9, and the extended portion E may be electrically connected to the access transistor through the lower electrode contact plug 13. The extended portion E of the lower electrode 3 may limit increases in integration densities of magnetic RAM devices.

Even though a magnetic RAM device may provide advantages of relatively high speed, low power consumption, and high reliability, increased integration densities may be difficult to achieve. Accordingly there are continuing efforts to improve integration densities of magnetic RAM devices. For example, a magnetic thermal RAM without digit lines is disclosed in U.S. Pat. No. 6,385,082 entitled “Thermally-assisted magnetic random access memory” to Abraham, et. al. The disclosure of U.S. Pat. No. 6,385,082 is hereby incorporated herein in its entirety by reference.

### SUMMARY

According to embodiments of the present invention, a magnetic random access memory device may include a semiconductor substrate, a magnetic tunnel junction (MTJ) structure, a contact plug, and a digit line. The magnetic tunnel junction (MTJ) structure may be provided on the semiconductor substrate, and the digit line may be provided adjacent the magnetic tunnel junction structure. In addition, the contact plug may provide electrical connection between the magnetic tunnel junction structure and the semiconductor substrate with the contact plug being provided between the magnetic tunnel junction structure and the semiconductor substrate.

More particularly, the digit line may be provided between the magnetic tunnel junction structure and the semiconductor substrate, and the digit line may be spaced apart from the contact plug. In addition, an electrode may be electrically connected between the magnetic tunnel junction structure and the contact plug. The magnetic tunnel junction structure may include a pinning layer, a pinned ferromagnetic layer, a tunnel insulating layer, and a free ferromagnetic layer. For example, the magnetic tunnel junction structure may include a ferromagnetic layer, and the contact plug may be provided between the semiconductor substrate and the ferromagnetic layer.

The magnetic tunnel junction structure may have a length in a longitudinal direction parallel to a surface of the substrate greater than a width in a transversal direction parallel to the surface of the substrate, and the contact plug may be between the semiconductor substrate and one end of the magnetic tunnel junction structure in the longitudinal direction. More particularly, the digit line may be arranged in a direction perpendicular to the longitudinal direction of the magnetic tunnel junction structure, and the digit line may have a width less than a length of the magnetic tunnel junction structure. Moreover, the digit line may be off-center relative to the magnetic tunnel junction structure in the longitudinal direction of the magnetic tunnel junction structure. The digit line may also be between the magnetic tunnel junction structure and the semiconductor substrate.

A bit line may also be electrically connected to the magnetic tunnel junction structure with the magnetic tunnel junction structure being between the bit line and the semiconductor substrate. In addition, a memory cell access transistor may be provided on the semiconductor substrate, and the contact plug may be electrically connected to a source/drain region of the memory cell access transistor. The magnetic tunnel junction structure may be between first and second electrodes. More particularly, the first electrode may be between the magnetic tunnel junction structure and the contact plug, the second electrode may be between the magnetic tunnel junction structure and the bit line, and each of the first and second electrodes may include titanium and/or tantalum. Moreover, the first electrode, the magnetic tunnel junction structure, and the second electrode may be aligned in dimensions parallel to a surface of the substrate.

According to additional embodiments of the present invention, a method of forming a magnetic random access memory device may include forming a digit line on a semiconductor substrate, and forming a contact plug on the semiconductor substrate. A magnetic tunnel junction (MTJ) structure may be formed on the semiconductor substrate with the contact plug providing electrical connection between the magnetic tunnel junction structure and the semiconductor substrate. Moreover, the contact plug may be between the magnetic tunnel junction structure and the semiconductor substrate, and the digit line may be adjacent the magnetic tunnel junction structure.

The digit line may be between the magnetic tunnel junction structure and the semiconductor substrate, and the digit line may be spaced apart from the contact plug. In addition, an electrode may be formed with the electrode being electrically connected between the magnetic tunnel junction structure and the contact plug. Moreover, forming the magnetic tunnel unction structure may include forming a pinning layer, a pinned ferromagnetic layer, a tunnel insulating layer, and a free ferromagnetic layer. In addition, forming the magnetic tunnel junction structure may include forming a ferromagnetic layer, and the contact plug may be between the semiconductor substrate and the ferromagnetic layer.

Moreover the magnetic tunnel junction structure may have a length in a longitudinal direction parallel to a surface of the substrate greater than a width in a transversal direction parallel to the surface of the substrate, and the contact plug may be between the semiconductor substrate and one end of the magnetic tunnel junction structure in the longitudinal direction. A length of the digit line may be arranged in a direction perpendicular to the longitudinal direction of the magnetic tunnel junction structure, and the digit line may have a width less t h a n a length of the magnetic tunnel junction structure. The digit line may be off-center relative to the magnetic tunnel junction structure in the longitudinal direction of the magnetic tunnel junction structure, and the digit line may be between the magnetic tunnel junction structure and the semiconductor substrate.

A bit line may also be formed with the bit line being electrically connected to the magnetic tunnel junction structure, and the magnetic tunnel junction structure may be between the bit line and the semiconductor substrate. In addition, a memory cell access transistor may be formed on the semiconductor substrate, and the contact plug may be electrically connected to a source/drain region of the memory cell access transistor. Moreover, first and second electrodes may be formed with the magnetic tunnel junction structure being formed therebetween. More particularly, the first electrode may be between the magnetic tunnel junction structure and the contact plug, the second electrode may be between the magnetic tunnel junction structure and the bit line, and each of the first and second electrodes may include titanium and/or tantalum. The first electrode, the magnetic tunnel junction structure, and the second electrode may be aligned in dimensions parallel to a surface of the substrate. More particularly, forming the first electrode, the magnetic tunnel junction structure, and the second electrode may include patterning the first electrode, the magnetic tunnel junction structure, and the second electrode using a single photolithographic mask.

According to still additional embodiments of the present invention, a magnetic random access memory device may include a semiconductor substrate, a magnetic tunnel junction (MTJ) structure, a contact plug, and a digit line. The magnetic tunnel junction (MTJ) structure may be provided on the semiconductor substrate, and the magnetic tunnel junction structure may have a length in a longitudinal direction parallel to a surface of the substrate. The contact plug may provide electrical connection between the magnetic tunnel junction structure and the semiconductor substrate. The digit line may be provided between the magnetic tunnel junction structure and the semiconductor substrate. More particularly, the digit line may be arranged in a direction perpendicular to the longitudinal direction of the magnetic tunnel junction structure, and the digit line may be off-center relative to the magnetic tunnel junction structure in the longitudinal direction of the magnetic tunnel junction structure.

Embodiments of the present invention may thus provide magnetic random access memory (MRAM) devices with increased integration densities.

According to some embodiments of the present invention, a MRAM device may include a lower electrode on a semiconductor substrate, and a magnetic tunnel junction (MTJ) structure may be disposed on the lower electrode. A lower electrode contact plug may be disposed between the lower electrode and the substrate, and the lower electrode contact plug may be in contact with a bottom surface of the lower electrode. The lower electrode may also overlap a portion of the MTJ structure. A digit line may be disposed below the MTJ structure, and the digit line may be spaced apart from the lower electrode contact plug.

The MTJ structure may have a length and a width from a plan view such that the lower electrode contact plug overlaps one end of the MTJ structure in a longitudinal direction of the MTJ structure. The lower electrode may have substantially a same plane area as that of the MTJ structure. The digit line may be disposed perpendicular with respect to a longitudinal direction of the MTJ structure, and the digit line may have a width smaller than a length of the MTJ structure. The digit line and the lower electrode contact plug may overlap the MTJ structure.

An upper electrode may be disposed on the MTJ structure, and a bit line running across the digit line may be electrically connected to the upper electrode. An access transistor may also be formed on the semiconductor substrate below the digit line. In this case, the lower electrode contact plug may be electrically connected to a drain region of the access transistor.

According to some other embodiments of the present invention, a method of fabricating a high density MRAM device may include forming a first interlayer insulating layer on a semiconductor substrate. A digit line may be formed on the first interlayer insulating layer. A second interlayer insulating layer may be formed covering the digit line. A lower electrode contact plug may be formed wherein the lower electrode contact plug penetrates at least the second interlayer insulating layer. A magnetic resistor may be formed on the second interlayer insulating layer having the lower electrode contact plug, and the magnetic resistor may include a lower electrode, a magnetic junction structure and an upper electrode, which are sequentially stacked. The magnetic junction structure may be formed to overlap the digit line and the lower electrode contact plug.

The MTJ structure may be formed to have a length in a direction perpendicular to the digit line from a plan view. A third interlayer insulating layer covering the magnetic resistor may be formed on the second interlayer insulating layer. A bit line may be formed on the third interlayer insulating layer to run across the digit line, and the bit line may be electrically connected to the upper electrode through a bit line contact hole penetrating the third interlayer insulating layer.

### BRIEF DESCRIPTION OF THE DRAWINGS

FIG. 1 is a cross-sectional view illustrating a cell of a conventional magnetic random access memory (MRAM) device.

FIG. 2 is a plan view illustrating a unit cell of a magnetic RAM device according to embodiments of the present invention.

FIG. 3 is a cross-sectional view taken along the line I˜I′ of FIG. 2.

FIGS. 4 through 7 are cross-sectional views taken along the line I˜I′ of FIG. 2 to illustrate methods of fabricating magnetic RAM devices according to embodiments of the present invention.

FIG. 8 is a graph of asteroid curves illustrating switching characteristics of magnetic tunnel junction (MTJ) structures in accordance with positions of a digit line.

FIG. 9 is a graph of asteroid curves illustrating switching characteristics of MTJ structures in accordance with widths of a digit line.

### DETAILED DESCRIPTION OF THE INVENTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

In the drawings, thickness and/or widths of layers, regions, and/or lines are exaggerated for clarity. It will also be understood that when an element such as a layer, region or substrate is referred to as being on another element, it can be directly on the other element or intervening elements may also be present. In contrast, if an element such as a layer, region or substrate is referred to as being directly on another element, then no other intervening elements are present. As used herein, the term and/or includes any and all combinations of one or more of the associated listed items.

Embodiments of the invention are described herein with reference to cross-section illustrations that are schematic illustrations of idealized embodiments (and intermediate structures) of the invention. The thickness, lengths, and/or widths of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Moreover, vertically aligned layers may be undercut and/or overcut relative to one another due to variations in etch selectivity when etching multiple self-aligned layers using a single photolighographic or other mask. Thus, the regions illustrated in the figures are schematic in nature and their shapes are not intended to illustrate the actual shape of a region of a device and are not intended to limit the scope of the invention.

Furthermore, relative terms, such as beneath, over, under, upper, and/or lower may be used herein to describe one element's relationship to another element as illustrated in the figures. It will be understood that relative terms are intended to encompass different orientations of the device in addition to the orientation depicted in the figures. For example, if the device in one of the figures is turned over, elements described as below other elements would then be oriented above the other elements. The exemplary term below, can therefore, encompasses both an orientation of above and below.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second region, layer or section could be termed a first region, layer or section without departing from the teachings of the present invention. Like numbers refer to like elements throughout.

The terminology used herein is for the purpose of describing particular embodiments only and is not intended to be limiting of the invention. As used herein, the singular forms “a” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

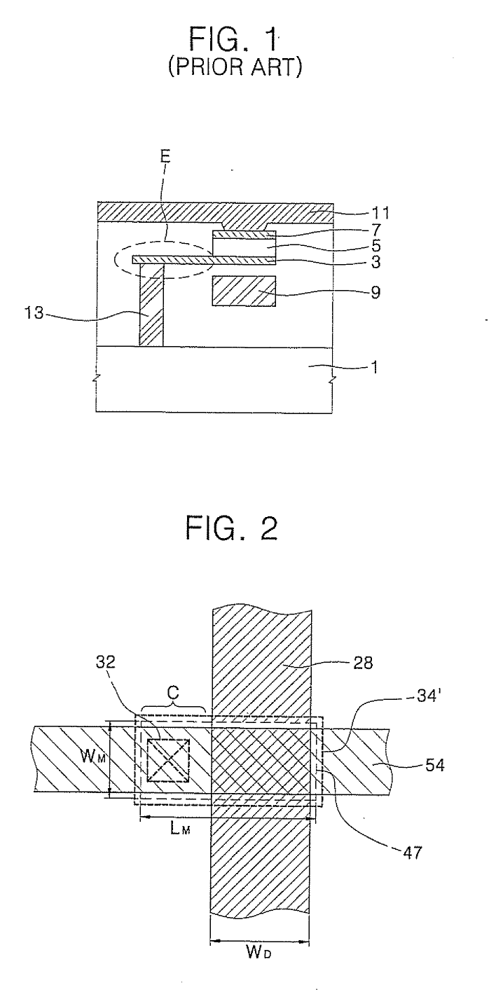

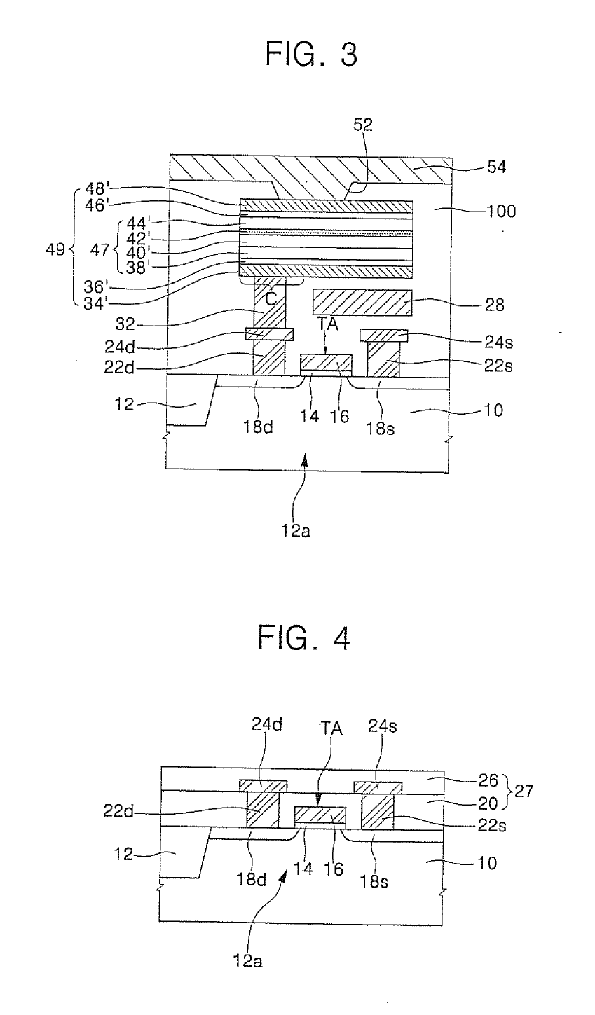

FIG. 2 is a plan view illustrating a unit cell of a magnetic random access memory (MRAM) device according to embodiments of the present invention, and FIG. 3 is a cross-sectional view taken along the line I˜I′ of FIG. 2. Referring to FIGS. 2 and 3, an access device may be formed in a region of a semiconductor substrate 10, and the access device may be a MOS transistor. Here, the access transistor TA is disposed in an active region 12a of the substrate 10 isolated by a isolation layer 12 formed in another region of the semiconductor substrate 10. More particularly, the access transistor TA may include a source region 18s and a drain region 18d formed in the active region 12a and spaced from each other, and a gate electrode 16 disposed on a channel region between the source region 18s and the drain region 18d. The gate electrode 16 may extend across the active region 12a, and may function as a word line. The gate electrode 16 may be insulated from the active region 12a by a gate insulating layer 14.

A drain pad 24d and a common source line 24s may be disposed on the substrate including the access transistor TA. The drain pad 24d may be electrically connected to the drain region 18d through a drain contact plug 22d, and the common source line 24s may be electrically connected to the source region 18s through a source contact plug 22s. The drain pad 24d and the common source line 24s may be disposed at a same level over the semiconductor substrate 10. The drain region 18d may be an output terminal of the access transistor TA. The common source line 24s may be electrically connected to a ground terminal, and may be disposed in parallel with respect to the gate electrode 16 functioning as a word line.

A magnetic resistor 49 may be disposed on the substrate having the common source line 24s and the drain pad 24d. The magnetic resistor 49 may include a lower electrode 34′, a magnetic tunnel junction (MTJ) structure 47, and an upper electrode 48′, which are sequentially stacked. The MTJ structure 47 may have a rectangular shape with a length L_{M} (parallel with respect to the substrate 10) and a width W_{M} (parallel with respect to the substrate 10) shown in the plan view of FIG. 2. In an alternative, the MTJ structure 47 may have another shape such as an elliptical shape. Here, the MTJ structure 47 may have a length LM in a direction perpendicular with respect to a direction of the gate electrode 16 functioning as a word line. The lower electrode 34′ and the upper electrode 48′ may have substantially the same areas as that of the MTJ structure 47.

The MTJ structure 47 may include a pinning layer pattern 38′, a pinned layer pattern 40′, a tunneling insulating layer pattern 42′, and a free layer pattern 44′, which are sequentially stacked. The pinning layer pattern 38′ may be formed of an anti-ferromagnetic layer such as a PtMn layer, and the free layer pattern 44′ and the pinned layer pattern 40′ may include ferromagnetic layers. Each ferromagnetic layer may include a NiFe layer, a CoFe layer, and/or a CoFeB layer. Magnetic spins inside the pinned layer pattern 40′ (in contact with the pinning layer pattern 38′) may have fixed magnetic spins always aligned along a specific direction due to the pinning layer pattern 38′ (i.e., due to the presence of the anti-ferromagnetic layer). The specific direction may be any one direction parallel with respect to a longitudinal direction of the MTJ structure 47. The tunneling insulating layer pattern 42′ may be an insulating layer such as an aluminum oxide (Al₂O₃) layer, a hafnium oxide (HfO) layer, and/or a tantalum oxide (TaO) layer.

The pinned layer pattern 40′ and the free layer pattern 44′ may be single ferromagnetic layers and/or synthetic anti-ferromagnetic (SAF) layers. An SAF layer may include a lower ferromagnetic layer, an upper ferromagnetic layer, and an anti-ferromagnetic coupling spacer layer interposed therebetween. An anti-ferromagnetic coupling spacer layer may include a ruthenium layer.

The magnetic resistor 49 may further include a seed layer pattern 36′ between the lower electrode 34′ and the pinning layer pattern 38′, and/or a capping layer pattern 46′ between the upper electrode 48′ and the free layer pattern 44′. The seed layer pattern 36′ may be formed to control a direction of a crystalline structure of the pinning layer pattern 38′. The capping layer pattern 46′ may provide a protecting layer of the MTJ structure 47.

A digit line 28 may be provided between the magnetic resistor 49 and the substrate 10. More particularly, the digit line 28 may be located between the lower electrode 34′ and the common source line 24s, and may be insulated from the lower electrode 34′ and the common source line 24s. The digit line 28 may be disposed perpendicular to a longitudinal direction of the MTJ structure 47 (e.g., in parallel with the gate electrode 16 functioning as a word line).

In embodiments of the present invention, the digit line 28 may be disposed to run across the magnetic resistor 49 such that a contact region C is disposed on the bottom surface of the lower electrode 34′ and partially overlaps the MTJ structure 47. The contact region C may be located at an end portion of the MTJ structure 47 in the longitudinal direction thereof. The digit line 28 is disposed below another end portion of the MTJ structure 47, but does not overlap an entire length LM of the MTJ structure 47. As a result the contact region C may be disposed on the bottom surface of the lower electrode 34′ below the portion of the MTJ structure 47 which does not overlap the digit line 28. Further, the digit line 28 may have the width WD less than the length LM of the MTJ structure 47. In this case, the digit line 28 is disposed below one end portion of the MTJ structure 47 as shown in FIG. 3, and may partially overlap the MTJ structure 47.

The lower electrode 34′ of the magnetic resistor 49 may be electrically connected to the drain pad 24d through the lower electrode contact plug 32. Accordingly, the lower electrode 34′ may be electrically connected to the drain region 18d of the access transistor TA through the lower electrode contact plug 32, the drain pad 24d, and the drain contact plug 22d. According to embodiments of the present invention, the lower electrode contact plug 32 is spaced from the digit line 28, and is electrically connected to the contact region C of the lower electrode 34′. The lower electrode contact plug 32 may thus overlap one end of the MTJ structure 47 longitudinally. According to particular embodiments of the present invention, the digit line 28 and the lower electrode contact plug 32 may overlap the MTJ structure 47 as shown in FIG. 3.

In embodiments of the present invention as described above, the digit line 28 may be disposed below one end portion of the MTJ structure 47 in a longitudinal direction thereof. Further, the lower electrode contact plug 32 may be connected to the contact region C to overlap the MTJ structure 47. Thus, the lower electrode 34′ can be electrically connected to the drain region 18d without extending the lower electrode beyond the MTJ structure. According to embodiments of the present invention, the digit line 28, the lower electrode contact plug 32, and the access transistor TA can all be provided below the MTJ structure 47, thereby reducing a sectional area of the cell of a MRAM device.

Referring to FIGS. 2 and 3, the substrate including the magnetic resistor 49 may be covered with an interlayer insulating layer 100, and a bit line 54 may be provided on the interlayer insulating layer 100. The bit line 54 may be electrically connected to the magnetic resistor 49 through the upper electrode 48′ and the hit line contact hole 52 penetrating the interlayer insulating layer 100). The bit line 54 may be disposed to run across the digit line 28.

FIGS. 4 through 7 are cross-sectional views taken along the line I˜I′ of FIG. 2 to illustrate methods of fabricating magnetic RAM devices according to embodiments of the present invention. Referring to FIGS. 2 and 4, the isolation layer 12 may be formed in regions of the semiconductor substrate 10 to isolate the active region 12a. The access transistor TA may be formed on the active region 12a. The access transistor TA may be a MOS transistor including source region 18s and the drain region 18d spaced from each other, and gate electrode 16 on a channel region between the source region 18s and the drain region 11d as shown in FIG. 4. The gate electrode 16 may be formed to run across the active region 12a. In this case, the gate electrode 16 may extend to other memory cells and may function as a word line. The gate electrode 16 may be insulated from the active region 12a by a gate insulating layer 14.

A first lower interlayer insulating layer 20 may be formed on the substrate including the access transistor TA. The first lower interlayer insulating layer 20 may be patterned, thereby forming a source contact hole and a drain contact hole exposing portions of the source region 18s and the drain region 18d, respectively. A source contact plug 22s and a drain contact plug 22d may be formed in the source contact hole and the drain contact hole, respectively. A conductive layer may be formed on the substrate including the contact plugs 22s and 22d, and the conductive layer may be patterned, thereby forming a drain pad 24d in contact with the drain contact plug 22d, and a common source line 24s in contact with the source contact plug 22s. The common source line 24s may be formed parallel with respect to the gate electrode 16, and the common source line 24s may extend to other memory cells. Then, a first upper interlayer insulating layer 26 may be formed on the substrate including the drain pad 24d and the common source line 24s. The first lower interlayer insulating layer 20 and the first upper interlayer insulating layer 26 may together provide a first interlayer insulating layer 27.

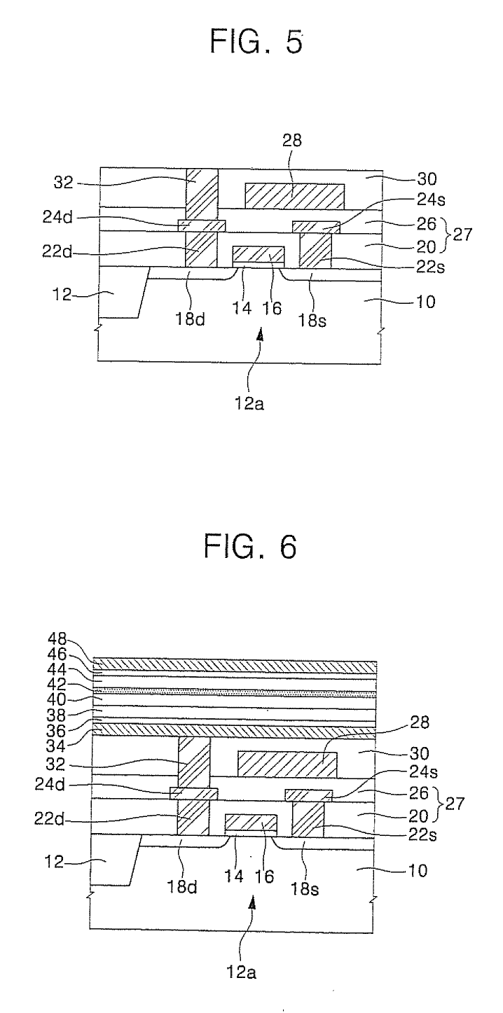

Referring to FIGS. 2 and 5, a digit line 28 may be formed on the first upper interlayer insulating layer 26. The digit line 28 may be formed parallel with respect to the gate electrode 16 and the common source line 24s. A second interlayer insulating layer 30 may be formed on the substrate including the digit line 28. The second interlayer insulating layer 30 and the first upper interlayer insulating layer 26 may be patterned to form a lower electrode contact hole exposing portions of the drain pad 24d, and a lower electrode contact plug 32 may be formed in the lower electrode contact hole.

Referring to FIGS. 2 and 6, a lower electrode layer 34, a seed layer 36, a pinning layer 38, a pinned layer 40, a tunneling insulating layer 42, a free layer 44, a capping layer 46, and an upper electrode layer 48 may be sequentially formed on the substrate including the lower electrode contact plug 32. The lower electrode layer 38 may include a titanium layer, a tantalum layer, and/or a titanium nitride layer, and the upper electrode layer 48 may include a tantalum layer. The seed layer 36 may include a NiFe layer and/or a NiFeCr layer, and the capping layer 46 may include a tantalum layer. In alternatives, the seed layer 36 and/or the capping layer 46 may be omitted. The pinning layer 38 may include an anti-ferromagnetic layer such as a PtMn layer, and the tunneling insulating layer 47 may include an insulating layer such as an aluminum oxide (Al₂O₃) layer.

The pinned layer 40 may include a single ferromagnetic layer and/or a synthetic anti-ferromagnetic layer. A single ferromagnetic layer may be formed by depositing a ferromagnetic material such as NiFe, CoFe, and/or CoFeB using a sputtering technique. In an alternative, the pinned layer 40 may be formed by sequentially stacking a lower ferromagnetic layer, an anti-ferromagnetic coupling spacer layer and an upper ferromagnetic layer if the pinned layer 40 is a synthetic anti-ferromagnetic layer. Each of the lower ferromagnetic layer and/or the upper ferromagnetic layer may be formed of a CoFe layer and/or an NiFe layer. The anti-ferromagnetic coupling spacer layer may be formed of a ruthenium layer.

Further, the free layer 44 may be a single ferromagnetic layer and/or a synthetic anti-ferromagnetic layer. More particularly, the free layer 44 may include a single ferromagnetic layer such as a NiFe layer, a CoFe layer, and/or a CoFeB layer. If the free layer 44 is the synthetic anti-ferromagnetic layer, the free layer 44 may be formed by sequentially stacking a lower ferromagnetic layer, an anti-ferromagnetic coupling spacer layer, and an upper ferromagnetic layer. Each of the lower ferromagnetic layer and the upper ferromagnetic layer may be a CoFe layer and/or a NiFe layer. The anti-ferromagnetic coupling spacer layer may be a ruthenium layer.

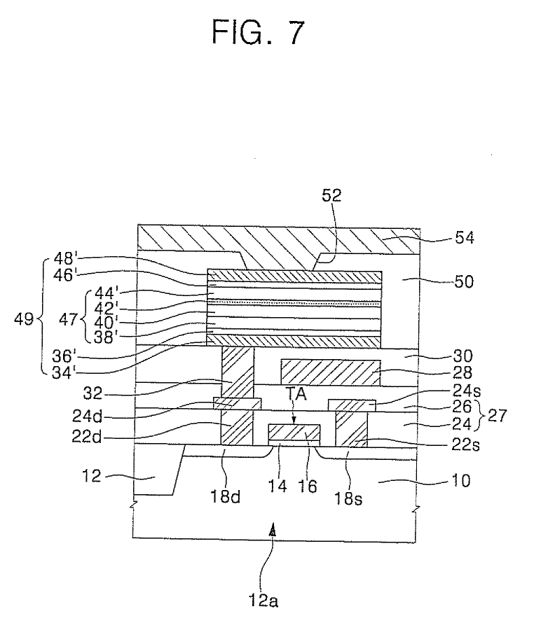

Referring to FIGS. 2 and 7, the upper electrode layer 48, the capping layer 46, the free layer 44, the tunneling insulating layer 42, the pinned layer 40, the pinning layer 38, the seed layer 36, and the lower electrode layer 34 may be sequentially patterned, thereby forming a magnetic resistor 49 on the second interlayer insulating layer 30. More particularly, these layers may be etched using a single photolithographic mask so that these layers are self-aligned. The resulting magnetic resistor 49 may thus include a lower electrode 34′, a seed layer pattern 36′, an MTJ structure 47, a capping layer pattern 46′ and an upper electrode 48′, which are sequentially stacked on the second interlayer insulating layer 30. The MTJ structure 47 may include a pinning layer pattern 38′, a pinned layer pattern 40′, a tunneling insulating layer pattern 42′, and a free layer pattern 44′, which are sequentially stacked. The lower electrode 34′, the MTJ structure 47 and the upper electrode 48′ may have substantially the same plane shapes (e.g. substantially the same lengths Lₘ and widths Wₘ).

The magnetic resistor 49 may be formed to have a predetermined length LM in a direction perpendicular to the digit line 28, and to overlap the digit line 28 and the lower electrode contact plug 32 as shown in FIG. 7. As a result, the lower electrode contact plug 32 may be connected to the lower electrode 34′ to overlap one end of the MTJ structure 47 in the longitudinal direction of the structure 47.

Then, a third interlayer insulating layer 50 may be formed on the substrate including the magnetic resistor 49. The third interlayer insulating layer 50 may be patterned, thereby forming a bit line contact hole 52 exposing portions of the upper electrode 48′. A conductive layer such as an aluminum layer may then be formed on the substrate including the bit line contact hole 52, and the conductive layer may be patterned, thereby forming a bit line 54 electrically connected to the upper electrode 48′ through the bit line contact hole 52. The bit line 54 may be formed to run across the digit line 29.

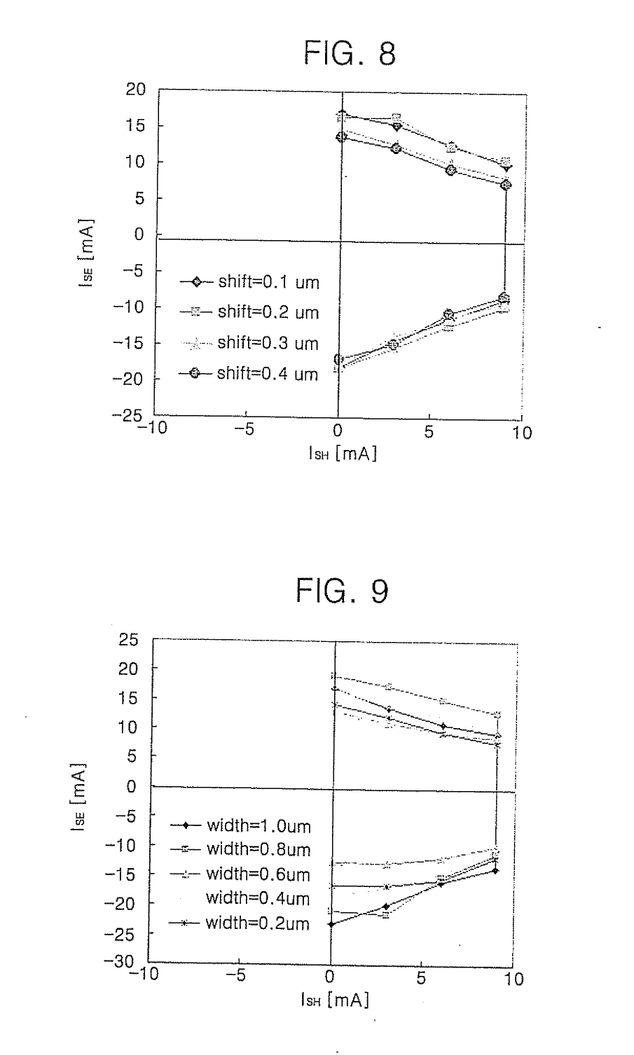

Switching characteristics of an MTJ structure will now be discussed with respect to locations and widths of digit lines. FIG. 8 is a graph of asteroid curves illustrating switching characteristics of MTJ structures as a function of digit line positions. In FIG. 8, the abscissa represents a hard axis current I_{SH} to generate a hard magnetic field, and the ordinate represents an easy axis current I_{SE} to generate an easy magnetic field.

MTJ structures showing the measurement results of FIG. 8 may be formed to have a rectangular shape with 0.8 μm of length L_{M} and 0.4 μm of width W_{M} from the plan view. Further, the MTJ structures may be formed to have a pinning layer pattern, a pinned layer pattern, a tunneling insulating layer pattern, and a free layer pattern, which are sequentially stacked. In this case, the pinning layer pattern is formed of a PtMn layer, and the tunneling insulating layer pattern is formed of an aluminum oxide layer. Further, the pinned layer pattern is formed of a synthetic anti-ferromagnetic layer by sequentially stacking a CoFe layer, a Ru layer and a CoFe layer; and the free layer pattern is formed of a CoFeB layer. The digit lines may be formed between the MTJ structures and substrates to run across the MTJ structures in the longitudinal direction of the structure. In this case, the digit lines are formed vertically spaced from the MTJ structures with about 1000 Angstroms of separation therebetween. The digit lines and the MTJ structures may be separated from each other by a silicon oxide layer (e.g. insulating layer 30). The digit lines may be aluminum layers having 1 μm of width and 0.6 μm of thickness. The results of FIG. 8 illustrate asteroid curves of the MTJ structures when the digit lines are formed having horizontal shifts from one longitudinal direction of the MTJ structure of 0.1 μm, 0.2 μm, 0.3 μm, and 0.4 μm respectively. Each shift distance is a distance between a center of the width of the digit line and a center of the length of the MTJ structure.

Referring to FIG. 8, minimum easy axis currents in accordance with the shift of the digit lines are measured at 17.5 mA, 17.4 mA, 16.3 mA, and 15.3 mA when the shift distances are 0.1 μm, 0.2 μm, 0.3)μm, and 0.4 μm, respectively. A minimum easy axis current is an easy axis current to switch the MTJ structure without the hard axis current. In the graph of FIG. 8, each minimum easy axis current is represented as an average value of the points where the ordinate meets respective asteroid curves. As shown in the graph, the switching current of the MTJ structure may be reduced when the shift distance is increased, and a write margin may not be reduced. These results show that switching characteristics of an MTJ structure may be improved if the digit line is shifted toward one direction without overlapping a center portion of the MTJ structure.

FIG. 9 is a graph of asteroid curves illustrating switching characteristics of MTJ structures with respect to widths of a digit line. In FIG. 9, the abscissa represents a hard axis current I_{SH} to generate a hard magnetic field, and the ordinate represents an easy axis current I_{SE} to generate an easy magnetic field.

MTJ structures showing the measurement results of FIG. 9 may be formed using a same process as described with reference to FIG. 8. The digit lines may be formed between the MTJ structures and substrates to run across the MTJ structures in a longitudinal direction of the structure. In this case, the digit lines may be spaced from the MTJ structures with about 1000 Angstroms of separation therebetween. The digit lines and the MTJ structures may be separated from each other by the silicon oxide layer (e.g. a portion of insulating layer 30). The digit lines may be aluminum layers having with a thickness of 0.6 μm. The results of FIG. 8 illustrate asteroid curves of the MTJ structures when the digit lines are formed with widths of 1 μm, 0.8 μm, 0.6 μm, 0.4 μm and 0.3 μm, respectively. In each case, the digit lines may be formed to run across middle portions of (e.g. centered with respect to) the MTJ structures in longitudinal directions thereof.

Referring to FIG. 9, when a width of a digit line is 1 μm, 0.8 μm, 0.6 μm, 0.4 μm and 0.3 μm, a minimum easy axis current may be 20 mA, 20 mA, 12.8 mA, 17.5 mA, and 15.3 mA, respectively. Minimum easy axis current means an easy axis current to switch an MTJ structure without a hard axis current. In the graph of FIG. 9, each minimum easy axis current is represented as an average value of two points where the ordinate meets respective asteroid curves. When a width of the digit line is reduced, a switching current of an MTJ structure may be reduced.

According to embodiments of the present invention, FIGS. 8 and 9 show that switching characteristics of an MTJ structure 47 may be improved if the digit line 28 is has a width WD smaller than a length LM of the MTJ structure 47, and/or if the digit line 28 is disposed to run across one end of the MTJ structure 47. Because the digit line 28 is disposed to run across one end of the MTJ structure 47 between the MTJ structure 47 and the substrate 10, one end of the MTJ structure 47 may overlap the lower electrode contact plug 32 in a longitudinal direction of the MTJ structure 47. Because the lower electrode does not extend laterally beyond the MTJ structure, a sectional area of the cell of a MRAM device may be reduced. Integration densities of a magnetic RAM device may be increased using MTJ, digit line, and/or contact structures according to embodiments of the present invention.

While the present invention has been particularly shown and described with reference to embodiments thereof, it will be understood by those skilled in the art that various changes in form and details may be made therein without departing from the spirit and scope of the invention as defined by the appended claims and their equivalents.

That which is claimed is:

1. A magnetic random access memory device comprising:
a semiconductor substrate;
a magnetic tunnel junction (MTJ) structure on the semiconductor substrate;
a contact plug providing electrical connection between the magnetic tunnel junction structure and the semiconductor substrate wherein the contact plug is between the magnetic tunnel junction structure and the semiconductor substrate; and
a digit line adjacent the magnetic tunnel junction structure wherein the digit line is between the magnetic tunnel junction structure and the semiconductor substrate and wherein the digit line is spaced apart from the contact plug.

2. A magnetic random access memory device according to claim 1 further comprising:
an electrode electrically connected between the magnetic tunnel junction structure and the contact plug.

3. A magnetic random access memory device according to claim 1 wherein the magnetic tunnel junction structure has a length in a longitudinal direction parallel to a surface of the substrate greater than a width in a transversal direction parallel to the surface of the substrate, wherein the contact plug is between the semiconductor substrate and one end of the magnetic tunnel junction structure in the longitudinal direction.

4. A magnetic random access memory device according to claim 3 wherein the digit line is arranged in a direction perpendicular to the longitudinal direction of the magnetic tunnel junction structure, and wherein the digit line has a width less than a length of the magnetic tunnel junction structure.

5. A magnetic random access memory device according to claim 4 wherein the digit line is off-center relative to the magnetic tunnel junction structure in the longitudinal direction of the magnetic tunnel junction structure.

6. A magnetic random access memory device according to claim 1 wherein the magnetic tunnel junction structure includes a pinning layer, a pinned ferromagnetic layer, a tunnel insulating layer, and a free ferromagnetic layer.

7. A magnetic random access memory device according to claim 1 wherein the magnetic tunnel junction structure includes a ferromagnetic layer and wherein the contact plug is between the semiconductor substrate and the ferromagnetic layer.

8. A magnetic random access memory device according to claim 1 further comprising:
a bit line electrically connected to the magnetic tunnel junction structure wherein the magnetic tunnel junction structure is between the bit line and the semiconductor substrate.

9. A magnetic random access memory device according to claim 8 further comprising:
a memory cell access transistor on the semiconductor substrate, wherein the contact plug is electrically connected to a source/drain region of the memory cell access transistor.

10. A magnetic random access memory device according to claim 8 further comprising:
a first electrode between the magnetic tunnel junction structure and the contact plug wherein the first electrode includes titanium and/or tantalum; and
a second electrode between the magnetic tunnel junction structure and the bit line wherein the second electrode includes titanium and/or tantalum.

11. A magnetic random access memory device according to claim 10 wherein the first electrode, the magnetic tunnel junction structure, and the second electrode are aligned in dimensions parallel to a surface of the substrate.

12. A magnetic random access memory device according to claim 10 wherein the first electrode, the magnetic tunnel junction stricture, and the second electrode have a same length and a same width in dimensions parallel to a surface of the substrate.

13. A magnetic random access memory device comprising:
a semiconductor substrate;
a magnetic tunnel junction (MTJ) structure on the semiconductor substrate wherein the magnetic tunnel junction structure has a length in a longitudinal direction parallel to a surface of the substrate;
a contact plug providing electrical connection between the magnetic tunnel junction structure and the semiconductor substrate; and
a digit line between the magnetic tunnel junction structure and the semiconductor substrate wherein the digit line is arranged in a direction perpendicular to the longitudinal direction of the magnetic tunnel junction structure, and wherein the digit line is off-center relative to the magnetic tunnel junction structure in the longitudinal direction of the magnetic tunnel junction structure.
